(19) United States
(12) Patent Application Publication
(10) Pub. No.: US 2018/0192543 A1
(43) Pub. Date: Jul. 5, 2018

(54) HEAT DISSIPATION MODULE AND MANUFACTURING METHOD THEREOF

(71) Applicant: Acer Incorporated, New Taipei City (TW)

(72) Inventors: Yung-Chih Wang, New Taipei City (TW); Jau-Han Ke, New Taipei City (TW); Wen-Neng Liao, New Taipei City (TW); Cheng-Yu Cheng, New Taipei City (TW); Cheng-Wen Hsieh, New Taipei City (TW)

(73) Assignee: Acer Incorporated, New Taipei City (TW)

(21) Appl. No.: 15/483,600

(22) Filed: Apr. 10, 2017

(30) Foreign Application Priority Data
Jan. 4, 2017 (TW) 106100127

(51) Int. Cl. H05K 7/20

(52) U.S. Cl. CPC H05K 7/20309; H05K 7/20336

(57) ABSTRACT

A heat dissipation module applicable to an electronic apparatus is provided. The electronic apparatus includes a heat source. The heat dissipation module includes an evaporator, a first pipe, and a working fluid. The evaporator includes a tank and a first sheet metal installed in the tank. The tank includes a cavity, and the first sheet metal includes a plurality of tabs that are arranged and stand in the cavity. The evaporator is in thermal contact with the heat source so as to absorb heat generated by the heat source. The first pipe is connected to the cavity to form a first loop. The working fluid is filled in the cavity and the first loop. In addition, a method for manufacturing the heat dissipation module is also provided.

### CROSS-REFERENCE TO RELATED APPLICATION

This application claims the priority benefit of Taiwan application serial no. 106100127, filed on Jan. 4, 2017. The entirety of the above-mentioned patent application is hereby incorporated by reference herein and made a part of this specification.

### BACKGROUND

### 1. Technical Field

The present invention relates to a heat dissipation module and a manufacturing method thereof, and in particular, to a heat dissipation module applicable to an electronic apparatus and a manufacturing method thereof.

### 2. Description of Related Art

With development of communications technologies, electronic apparatuses such as mobile phones and tablet computers already become necessities in life of modern people. In addition, as people increasingly rely on these electronic apparatuses, a usage time becomes longer. However, using an electronic apparatus for a long time often causes an integration circuit of the electronic apparatus to break down due to overheating. This is really inconvenient.

Currently, for a common heat dissipation module, for example, a heat dissipation module disclosed in the Taiwan Publication Patent Number 1558305, a state of a working fluid can change due to heat absorption when the working fluid flows through an evaporator, achieving an effect of dissipating heat out of an electronic apparatus. A plurality of copper cylinders are always disposed in an evaporator, so as to improve an area of contact between a working fluid and the evaporator, thereby improving heat transfer efficiency. However, machining, manufacturing, and assembling of a copper cylinder are relatively not easy, and designs to which the copper cylinder is applicable are relatively limited. In addition, the heat dissipation module generally includes only one loop, and heat dissipation effectiveness that can be achieved is still limited.

### SUMMARY

The present invention provides a heat dissipation module and a manufacturing method thereof, so as to improve heat dissipation effectiveness and simplify a manufacturing process by using a plurality of tabs disposed in an evaporator.

A heat dissipation module in the present invention is applicable to an electronic apparatus. The electronic apparatus includes a heat source. The heat dissipation module includes an evaporator, a first pipe, and a working fluid. The evaporator includes a tank and a first sheet metal installed in the tank. The tank includes a cavity, and the first sheet metal includes a plurality of tabs that are arranged and stand in the cavity. The evaporator is in thermal contact with the heat source so as to absorb heat generated by the heat source. The first pipe is connected to the cavity to form a first loop. The working fluid is filled in the cavity and the first loop.

Based on the foregoing, in the heat dissipation module in the present invention, after a first pipe is connected to a cavity of an evaporator to form a first loop, a working fluid is filled in the cavity. Therefore, the working fluid can smoothly absorb heat when running through the evaporator, the working fluid is then converted into a vapor state, and the heat is taken away when the working fluid flows out of the cavity of the evaporator, so as to achieve a heat dissipation effect. Moreover, the evaporator includes a tank and a sheet metal installed in the tank. The tank includes a plurality of tabs that are arranged and stand in the cavity, and the tabs can improve an area of contact between the working fluid and the evaporator, so as to improve heat transfer effectiveness and also simplify an existing copper-cylinder-shaped structure and a manufacturing process. In the method for manufacturing a heat dissipation module in the present invention, tabs need to be obtained by performing folding only from a bottom portion of a first sheet metal, and the first sheet metal can be directly welded to a tank. Machining, manufacturing, and assembling of the heat dissipation module are relatively easy, and are easily applicable to a plurality of designs.

In order to make the aforementioned and other objectives and advantages of the present invention comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a heat dissipation module according to a first embodiment of the present invention;

FIG. 2 is a locally enlarged diagram according to a first embodiment of the present invention;

FIG. 3 is a locally enlarged diagram of a section along a line I-I′ in FIG. 2;

FIG. 4 is a schematic flowchart of a method for manufacturing a heat dissipation module according to an embodiment of the present invention;

FIG. 5 is a locally enlarged diagram according to a second embodiment of the present invention;

FIG. 6 is a locally enlarged diagram according to a third embodiment of the present invention;

FIG. 7 is a locally enlarged diagram according to a fourth embodiment of the present invention;

FIG. 8 is a locally enlarged diagram according to a fifth embodiment of the present invention; and

FIG. 9 is a locally enlarged diagram according to a sixth embodiment of the present invention.

### DESCRIPTION OF THE EMBODIMENTS

Reference will now be made in detail to the present preferred embodiments of the invention, examples of which are illustrated in the accompanying drawings.

Wherever possible, the same reference numbers are used in the drawings and the description to refer to the same or like parts.

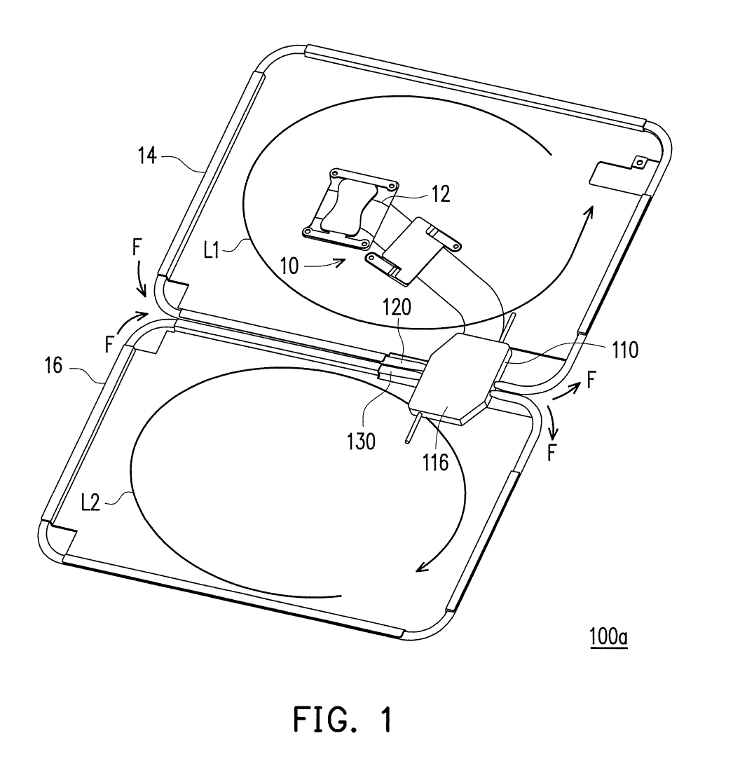

FIG. 1 is a schematic diagram of a heat dissipation module according to a first embodiment of the present invention. Referring to FIG. 1, in the present embodiment, a heat dissipation module 100a is applicable to an electronic apparatus. The electronic apparatus is, for example, but not limited to, a notebook computer or a tablet computer. The electronic apparatus includes a heat source 10, and the heat source 10 is, for example, but not limited to, a central processing unit or a display chip. The heat dissipation module 100a can absorb heat generated by the heat source 10, and therefore, dissipate the heat out of the electronic apparatus via another portion (for example, a housing) of the electronic apparatus.

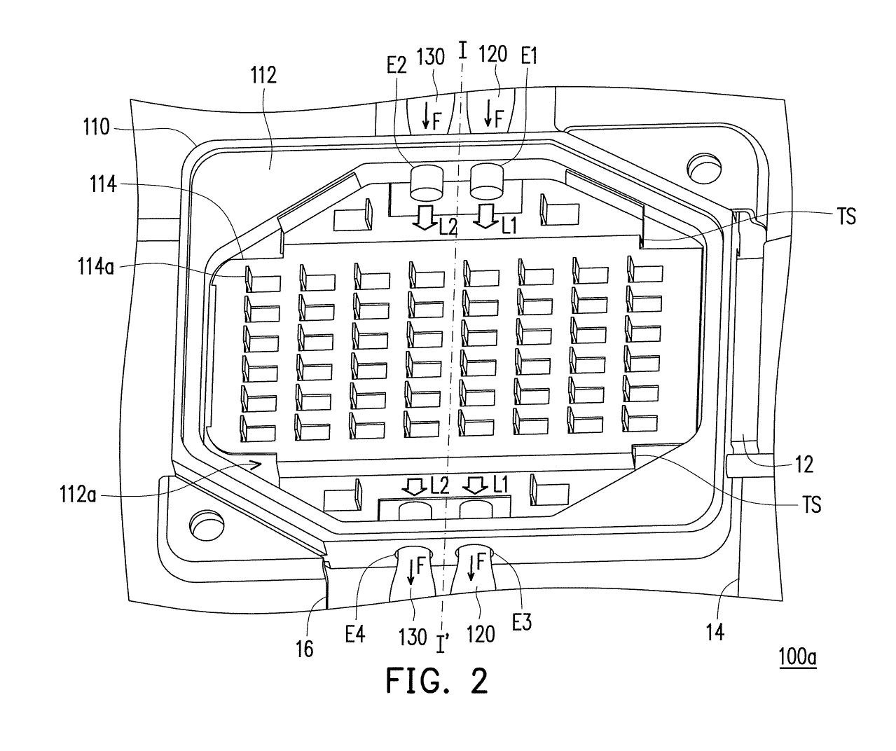

FIG. 2 is a locally enlarged diagram according to a first embodiment of the present invention. As shown in FIG. 1 and FIG. 2, the heat dissipation module 100a in the present embodiment includes an evaporator 110, a first pipe 120, a second pipe 130, and a working fluid F. The evaporator 110 includes a tank 112 and a first sheet metal 114 installed in the tank 112. The tank 112 includes a cavity 112a, and the first sheet metal 114 includes a plurality of tabs 114a that are arranged and stand in the cavity 112a. The evaporator 110 is in thermal contact with the heat source 10 so as to absorb heat generated by the heat source 10. The first pipe 120 is connected to the cavity 112a to form a first loop L1. The second pipe 130 is connected to the cavity 112a to form a second loop L2. The working fluid F is filled in the cavity 112a, the first loop L1, and the second loop L2.

Specifically, the cavity 112a in the present embodiment includes a first outlet E1, so as to connect to one end of the first pipe 120; and a first inlet E3 corresponding to the first outlet E1, so as to connect to the other end of the first pipe 120. The cavity 112a in the present embodiment is further provided with a second outlet E2, so as to connect to one end of the second pipe 130; and a second inlet E4 corresponding to the second outlet E2, so as to connect to the other end of the second pipe 130. When the working fluid F flows through the evaporator 110, a state of the working fluid F can change due to absorption of the heat from the heat source 10, for example, the working fluid F in liquid state is enabled to be transformed to the working fluid F in vapor state. As the working fluid F in vapor state moves away from the evaporator 110, the heat is taken away accordingly. When the working fluid F flows through another portion (for example, the foregoing house), which is in a relatively low temperature, of the electronic apparatus via the first pipe 120 and the second pipe 130, such that a phase-transformation (condensation) is performed on the working fluid F again (the working fluid F is transformed from the vapor state back to the liquid state), so as to dissipate the heat out of the electronic apparatus.

In the present embodiment, the evaporator 110 further includes the first sheet metal 114 installed into the tank 112. The first sheet metal 114 is installed into the tank 112, for example, in a welding manner, and the present invention is not limited thereto. The first sheet metal 114 is made of, for example, a metal material or another material having a high coefficient of thermal conductivity, and can effectively transfer the heat from the heat source 10. Therefore, when the working fluid F flows through the cavity 112a, a phase-transformation is quickly generated, so as to improve heat dissipation effectiveness. In the present embodiment, a bottom portion of the first sheet metal 114 is in contact with an inner bottom of the tank 112, and a part of the first sheet metal 114 is folded on a side wall of the tank 112. A height obtained by folding the first sheet metal 114 is equal to a height of the side wall of the tank 112. In this way, when a cover body 116 covers the tank 112 to form a contained space, the cover body 116 may directly abut on the first sheet metal 114, so that the first sheet metal 114 can be actually welded to the tank 112, thereby avoiding a lifted lead problem (wherein a gap existed between the cover body 116 and a top of the first sheet metal 114). In addition, to avoid squeezing out space of the first pipe 120 at the first outlet E1 and the first inlet E3 and space of the second pipe 130 at the second outlet E2 and the second inlet E4, local removal in structure may be performed on the first sheet metal 114 at the outlets E1 and E2 and at the inlets E3 and E4. The local removal of the first sheet metal 114 may also avoid unexpected flow impedance when the working fluid F flows into or out of the cavity 112a.

Further, the first sheet metal 114 in the present embodiment includes a plurality of tabs 114a that are arranged and stand in the cavity 112a. In addition, when the cover body 116 is assembled to the tank 112, the cover body 116 can actually abut on an upper portion of the tabs 114a, so that the tabs 114a provide an effect of supporting to the cover body 116 structurally. When the working fluid F flows through the cavity 112a, contact area between the working fluid F and the evaporator 110 is increased via the tabs 114a to improve heat exchanging efficiency of the evaporator, so that the working fluid F in liquid absorbs the heat, is transformed to the working fluid F in vapor state, and enters the first pipe 110 and the second pipe 120 via the first inlet E3 and the second inlet E4. In the present embodiment, the a plurality of tabs 114a are formed by folding a part of the first sheet metal 114 and are arranged in an array. The a plurality of tabs 114a may be, for example, in a rectangle, triangle, or square shape, and a height of the tabs 114a may be, for example, equal to or less than a height of the cavity 112a, or even half a height of the cavity 112a. The shape and size of the tabs 114a are not limited in the present invention. The tabs 114a in the cavity 112a are not limited to only one shape and size. In the present invention, the tabs 114a having multiple shapes and sizes may also be disposed in the cavity 112a as required. In addition, for example, the tabs 114a may vertically stand in the cavity 112a, or obliquely stand in the cavity 112a in an angle greater than or less than 90 degrees, or obliquely stand in the cavity 112a in a direction that is the same as or reverse to a flow direction of the working fluid F. A standing manner of the tabs 114a is not limited in the present invention. The tabs 114a in the cavity 112a are not limited to one standing manner. In the present invention, the tabs 114a having multiple standing manners may also be disposed in the cavity 112a as required. In the present embodiment, in addition to being arranged in a manner of being parallel with each other, the tabs 114a may also be arranged in a manner of being inclined to each other, or even arranged irregularly. Compared with a conventional copper cylinder, the a plurality of tabs 114 in the present invention can be readily obtained by folding a part of the first sheet metal 114, and can be in any shape, of any size, in any standing manner, or in any arrangement manner by processing the first sheet metal 114. Moreover, the a plurality of tabs 114a in the cavity 112a are not limited to one form. In the present invention, the tabs having a plurality of forms may be simultaneously disposed in the cavity 112a as required, so that the working fluid F in the cavity 112a is accordingly guided to the first loop L and the second loop L2. Details are described subsequently by using different embodiments.

The heat dissipation module 100a in the present embodiment further includes a second sheet metal 14 and a third sheet metal 16. The second sheet metal 14 and the third sheet metal 16 are made of, for example, a metal material, and may be a partial structure or complete structure of the electronic apparatus. The first pipe 120 is carried on the second sheet metal 14, and the second pipe 130 is carried on the third sheet metal 16. For example, the first pipe 120 and the second pipe 130 are respectively configured on peripheries of the second sheet metal 14 and the third sheet metal 16, and the second sheet metal 14 is not in direct contact with the third sheet metal 16. In the present embodiment, the second sheet metal 14 covers the heat source 10. Therefore, the second sheet metal 14 has larger area, and features of a metal material and the like, a better heat transfer effect can be provided. Therefore, when the working fluid F in vapor respectively flows through the first pipe 120 and the second pipe 130 from the first inlet E3 and the second inlet E4, a condensation effect can be achieved, and the working fluid F is transformed to the working fluid F in liquid, and flows back to the evaporator 110 via the first outlet E1 and the second outlet E2. In addition, the second sheet metal 14 may also assist in absorbing the heat from the heat source 10 to reduce heat flowing back to the heat source 10, and an effect of dissipation for the heat source 10 is also provided via the second sheet metal 14. In addition, the second sheet metal 14 and the third sheet metal 16 may also provide an effect of shielding electromagnetic interference (EMI) from the heat source 10 or another electronic element.

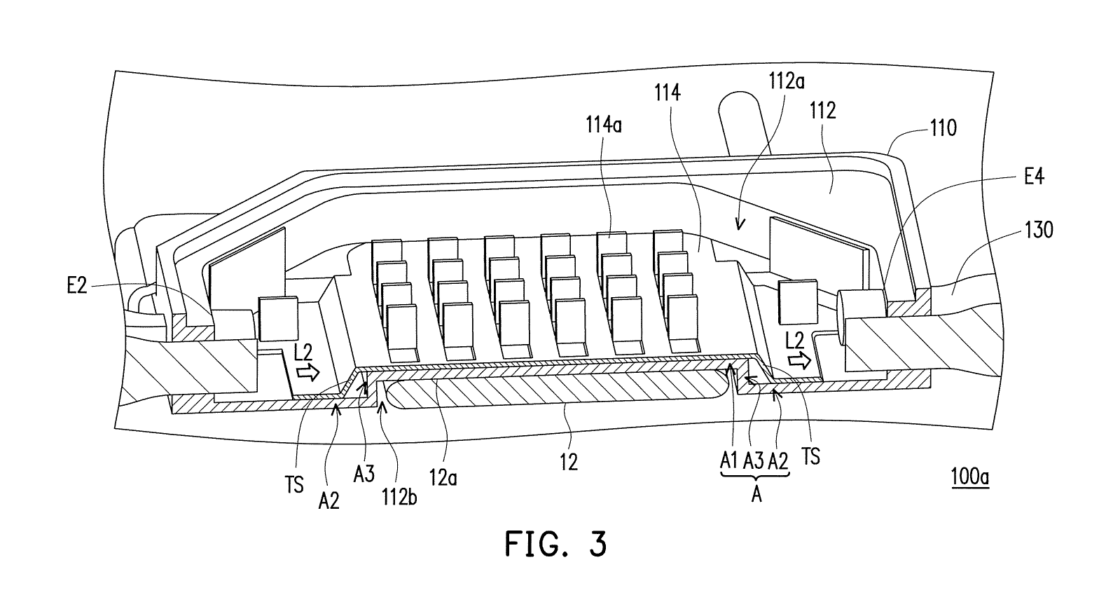

FIG. 3 is a locally enlarged diagram of a section along a line I-I′ in FIG. 2. In the present embodiment, the heat dissipation module 100a further includes a heat pipe 12, the heat pipe 12 is in thermal contact between the heat source 10 and the evaporator 110, so as to transfer the heat generated by the heat source 10 to the evaporator 110. The heat pipe 12 includes a contact section 12a abutting on the evaporator 110. An extending direction of the contact section 12a is not parallel with a flow direction of the working fluid F in the cavity 112a. That is, the flow direction of the working fluid F in the cavity 112a is from the first outlet E1 and the second outlet E2 to the first inlet E3 and the second inlet E4, and the extending direction of the contact section 12a is approximately perpendicular to the flow direction of the working fluid F in the cavity 112a. In this way, an area of contact between the heat pipe 12 and the evaporator 110 can be increased, thereby improving heat transfer efficiency and heat dissipation effectiveness.

In the present embodiment, a part out of the tank 112 includes a recess 112b, so as to form a step structure A on the cavity 112a. The contact section 12a of the heat pipe 12 is contacted in the recess 112b. The step structure A includes a higher step portion A1 and two lower step portions A2. The higher step portion A1 is located between the two lower step portions A2, and the two lower step portions A2 are respectively located at a joint between the cavity 112a and the first pipe 120 and at a joint between the cavity 112a and the second pipe 130. The step structure A further includes two side surfaces A3 that face towards each other. The two side surfaces A3 are respectively connected to the higher step portion A1 and the lower step portions A2, and face towards at least one inlet of E3 and E4 and at least one outlet of E1 and E2 of the cavity 112a. The first sheet metal 114 covers the higher step portion A1 of the step structure A, and the tabs 114a are located at the higher step portion A1 of the step structure A. An inclined plane TS is formed on a portion of the first sheet metal 114 corresponding to the two side surfaces A3 of the step structure A. When the working fluid F flows from the first pipe 120 and the second pipe 130 to the cavity 112a respectively via the first outlet E1 and the second outlet E2, and the inclined plane TS may assist in guiding the working fluid F to flow through the a plurality of tabs 114a located at the higher step portion A1, and assist in guiding the working fluid F to flow from the cavity 112a into the first inlet E3 and the second inlet E4 of the first pipe 120 and the second pipe 130 respectively. In this way, the working fluid F is not blocked at the first outlet E1 and the second outlet E2 due to a height difference between the higher step portion A1 and the lower step portions A2 of the step structure A, and heat dissipation efficiency of the heat dissipation module 100a is not affected.

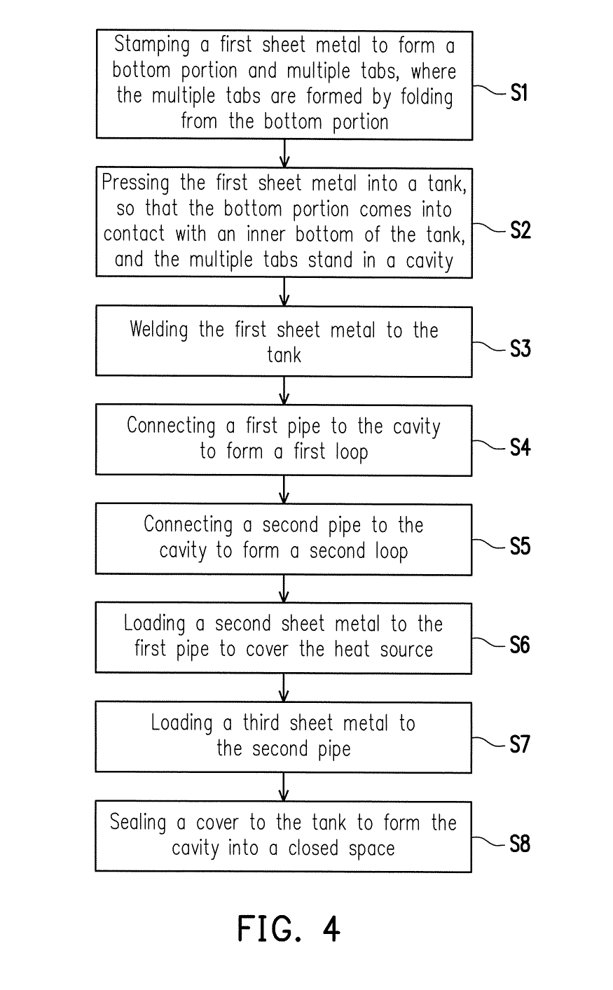

FIG. 4 is a schematic flowchart of a method for manufacturing a heat dissipation module according to an embodiment of the present invention. The method for manufacturing a heat dissipation module in the present invention is applicable to the heat dissipation modules of all the embodiments of the present invention or other heat dissipation modules conforming to the spirit of the present invention. Referring to FIG. 4, the method for manufacturing the heat dissipation module 100a in the present embodiment includes: first stamping a first sheet metal 114 to form a bottom portion and the tabs 114a, where the tabs 114a are formed by folding from the bottom portion (step S1). The first sheet metal 114 is easy to machine and manufacture, and the tabs 114a having multiple designs and arrangements can be formed through stamping (or punching) and by folding one sheet metal. Then, the first sheet metal 114 is pressed into a tank 112, so that the bottom portion comes into contact with an inner bottom of the tank 112, and the tabs 114a stand in a cavity 112a (step S2). The first sheet metal 114 is welded to the tank 112 (step S3). The first sheet metal 114 is assembled easily. The bottom portion is in contact with the inner bottom of the tank 112, and therefore, heat of a heat source 10 can be effectively transferred to the cavity 112a, and the first sheet metal 114 can be reliably assembled with the tank 112 through welding. The method for manufacturing a heat dissipation module in the present embodiment further includes: connecting the first pipe 120 to the cavity 112a, so as to form the first loop L1 (step S4); connecting the second pipe 130 to the cavity 112a, so as to form the second loop L2 (step S5); loading a second sheet metal 14 to the first pipe 120, and enabling the second sheet metal 14 to cover the heat source 10 (step S6); and loading a third sheet metal 16 to the second pipe 130 (step S7). For example, the first pipe 120 and the second pipe 130 are respectively configured on peripheries of the second sheet metal 14 and the third sheet metal 16, and the second sheet metal 14 is not in direct contact with the third sheet metal 16. Finally, the method for manufacturing a heat dissipation module in the present embodiment further includes: enabling a cover body 116 to cover the tank 112, so as to form a contained space (step S8), to prevent the working fluid F from flowing out of the evaporator 110, and to avoid lowering heat dissipation of the heat dissipation module 100a and damaging other electronic elements of the electronic apparatus.

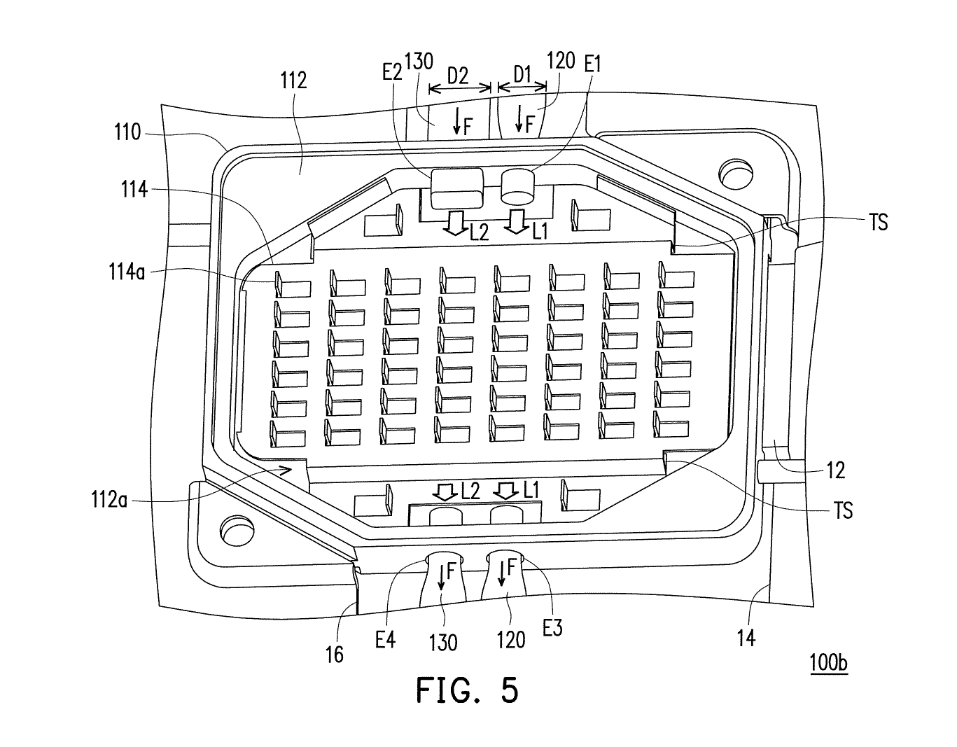

FIG. 5 is a locally enlarged diagram according to a second embodiment of the present invention. In the present embodiment, a flow rate of a working fluid F running through a first loop L1 is not equal to a flow rate of the working fluid F running through a second loop L2. Specifically, a heat source 10 of a heat dissipation module 100b in the present embodiment is in a range that is close to a first pipe 120, that is, close to the first loop L1. Therefore, a temperature of the working fluid F running through the first loop L1 is higher than a temperature of the working fluid F running through the second loop L2. In the present embodiment, by enabling the flow rate of the working fluid F running through the second loop L2 to be greater than the flow rate of the working fluid F running through the first loop L1, the working fluid F can take most heat from the first loop L1 to the second loop L2 for dissipation. Therefore, the heat is dissipated, so that a temperature in the first loop L1 and a temperature in the second loop L2 can be balanced, achieving a heat dissipation effect. Referring to FIG. 5, a second outlet E2 in the present embodiment is larger than a first outlet E1, and a pipe diameter D2 of a second pipe 130 is greater than a pipe diameter D1 of a first pipe 120. Therefore, when the working fluid F flows from the first outlet E1 and the second outlet E2 to the cavity 112a, the flow rate of the working fluid F running through the second loop L2 is greater than the flow rate of the working fluid F running through the first loop L1. In the present embodiment, by enabling the flow rate of the working fluid F running through the second loop L2 to be greater than the flow rate of the working fluid F running through the first loop L1, the working fluid F can take most heat from the first loop L1 to the second loop L2 for dissipation. Therefore, the heat is dissipated, so that the temperature in the first loop L1 and the temperature in the second loop L2 can be balanced, achieving a heat dissipation effect. On the contrary, for example, when the heat source 10 is relatively close to the second loop L2, the temperature of the working fluid F running through the second loop L2 is greater than the temperature of the working fluid F running through the first loop L2. Therefore, the first outlet E1 should be larger than the second outlet E2, and the pipe diameter D1 of the first pipe 120 should be greater than the pipe diameter D2 of the second pipe 130, so that the flow rate of the working fluid F running through the first loop L1 is greater than the flow rate of the working fluid F running through the second loop L2. The working fluid F can take most heat from the second loop L2 to the first loop L1 for dissipation. Therefore, the heat is dissipated, so that the temperature in the first loop L1 and the temperature in the second loop L2 can be balanced, achieving a heat dissipation effect.

In addition, besides the foregoing descriptions, for example, smoothness of inner walls of the first pipe 120 and the second pipe 130, surface energy of an inner wall (for example, surface processing such as coating and anode processing), a length, a bending angle, and a shape (such as circular and oval) of a cross section can be changed, but the present invention is not limited thereto. Even two ends or one end of the first pipe 120 and/or the second pipe 130 or a shape or a pipe diameter of the pipe is adjusted. Flow impedance of the working fluid F flowing in the first pipe 130 and the second pipe 130 is changed, so as to control the flows of the working fluids F in the first loop L1 and the second loop L2.

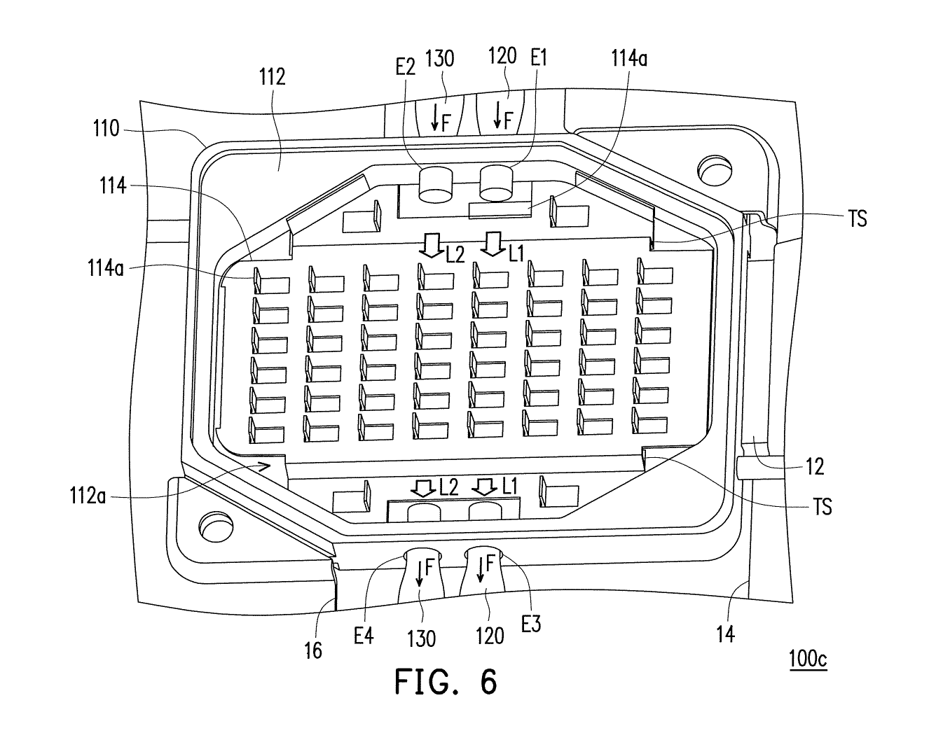

FIG. 6 is a locally enlarged diagram according to a third embodiment of the present invention. Referring to FIG. 6, in the present embodiment, at least one of the tabs 114a stands at a first outlet E1. In this way, when the working fluid F flows from a first pipe 120 to a cavity 112a via the first outlet E1, the working fluid F is blocked by the tabs 114a, so that more working fluids F flow to a second loop L2. When a heat source 10 of a heat dissipation module 100c is relatively close to a first loop L1, a temperature of the working fluid F running through the first loop L1 is greater than a temperature of the working fluid F running through the second loop L2. In the present embodiment, through blocking by the tabs 114a at the first outlet E1, the flow rate of the working fluid F running through the second loop L2 is enabled to be greater than the flow rate of the working fluid F running through the first loop L1, and the working fluid F can take most heat from the first loop L1 to the second loop L2 for dissipation. Therefore, the heat is dissipated, so that a temperature in the first loop L1 and a temperature in the second loop L2 can be balanced, achieving a heat dissipation effect. Certainly, the present invention is not limited thereto. For example, when the heat source 10 is relatively close to the second loop L2, the flow rate of the working fluid F running through the first loop L should be greater than the flow rate of the working fluid F running through the second loop L2, so that the working fluid F can take most heat from the second loop L2 to the first loop L1 for dissipation, achieving a heat dissipation effect. In this case, at least one of the a plurality of tabs 114a can be enabled to stand at the second outlet E2, so that the flow rate of the working fluid F running through the first loop L1 is greater than the flow rate of the working fluid F running through the second loop L2. In the present invention, locations of the tabs 114a can be changed as required, so as to block the working fluid F, so that the working fluid F has greater flow rate in a loop away from the heat source 10, and takes most heat from a loop close to the heat source 10 to a loop away from the heat source 10 for dissipation. Therefore, the heat is dissipated, so that a temperature in the first loop L1 and a temperature in the second loop L2 can be balanced.

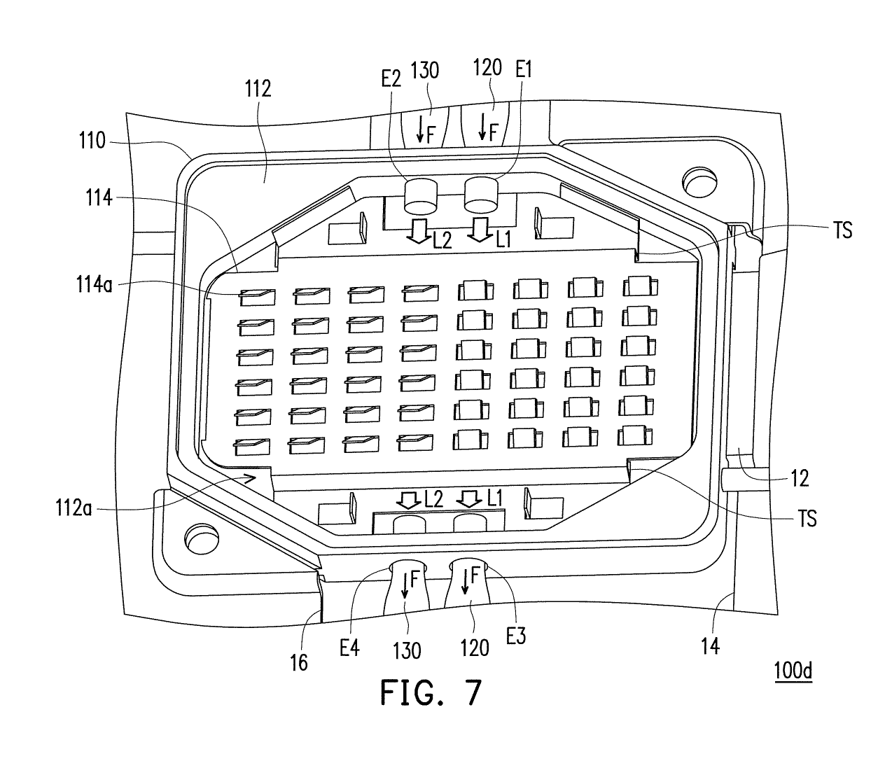

FIG. 7 is a locally enlarged diagram according to a fourth embodiment of the present invention. Referring to FIG. 7, in the present embodiment, some of the tabs 114a corresponding to a first loop L1 obliquely stand in a cavity 112a in a direction reverse to a flow direction of a working fluid F. Therefore, when flowing through the first loop L1, the working fluid F is subject to relatively high flow impedance. On the contrary, some of the tabs 114a corresponding to a second loop L2 obliquely stand in the cavity 112a in a direction forward (that is the same as) the flow direction of the working fluid F. Therefore, when flowing through the second loop L2, the working fluid F is subject to relatively low flow impedance. In this way, when the working fluid F flows from a first pipe 120 and a second pipe 130 to the cavity 112a respectively via a first outlet E1 and a second outlet E2, the tabs 114a guide the working fluid F to flow from the first loop L1 having relatively high flow impedance to the second loop L2 having relatively low flow impedance, so that a flow rate of the working fluid F running through the second loop L2 is greater than a flow rate of the working fluid F running through the first loop L1. When a heat source 10 of a heat dissipation module 100d is relatively close to the first loop L1, a temperature of the working fluid F running through the first loop L1 is greater than a temperature of the working fluid F running through the second loop L2. In the present embodiment, through guiding of the tabs 114a, the flow rate of the working fluid F running through the second loop L2 is enabled to be greater than the flow rate of the working fluid F running through the first loop L1, and the working fluid F can take most heat from the first loop L1 to the second loop L2 for dissipation. Therefore, the heat is dissipated, so that a temperature in the first loop L1 and a temperature in the second loop L2 can be balanced, achieving a heat dissipation effect. Certainly, the present invention is not limited thereto. For example, when the heat source 10 is relatively close to the second loop L2, the flow rate of the working fluid F running through the first loop L should be greater than the flow rate of the working fluid F running through the second loop L2, so that the working fluid F can take most heat from the second loop L2 to the first loop L1 for dissipation, achieving a heat dissipation effect. In this case, some of the tabs 114a corresponding to the first loop L1 can obliquely stand in the cavity 112a in the direction forward (that is the same as) the flow direction of the working fluid F, and some of the a plurality of tabs 114a corresponding to the second loop L2 can obliquely stand in the cavity 112a in the direction reverse to (against) the flow direction of the working fluid F. In the present invention, angles in which the tabs 114a stand can be changed as required, so as to guide the working fluid F, so that the working fluid F has greater flow rate in a loop away from the heat source 10, and takes most heat from a loop close to the heat source 10 to a loop away from the heat source 10 for dissipation. Therefore, the heat is dissipated, so that a temperature in the first loop L1 and a temperature in the second loop L2 can be balanced.

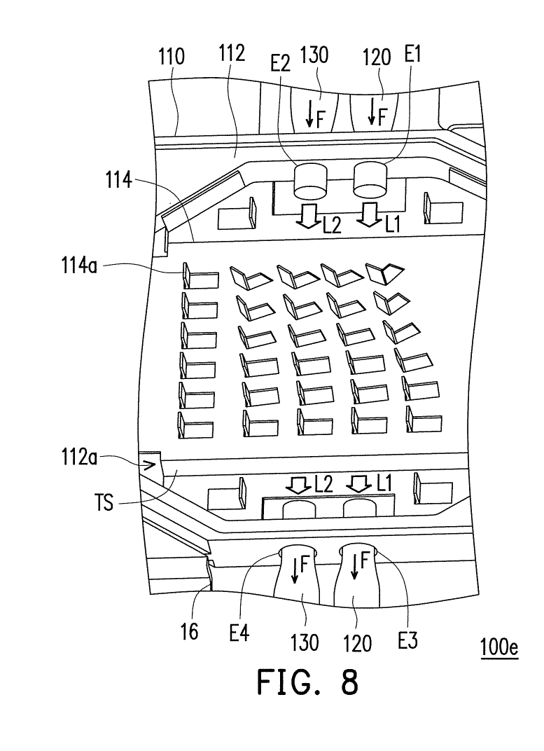

FIG. 8 is a locally enlarged diagram according to a fifth embodiment of the present invention. Referring to FIG. 8, in the present embodiment, some of a plurality of tabs 114a neighboring to a first outlet E1 and a second outlet E2 are centralized towards the second outlet E2. That is, some of the tabs 114a in the first loop L1 are arranged in a manner of being not parallel with the first pipe E1, and are obliquely arranged towards the second pipe E2. In this way, flow impedance to which the working fluid F in the first loop L1 is different from flow impedance to which the working fluid F in the second loop L2. When the working fluid F flows from the first pipe 120 and the second pipe 130 to the cavity 112a respectively via the first outlet E1 and the second outlet E2, and the tabs 114a guide the working fluid F, so that the flow rate of the working fluid F running through the second loop L2 is different from the flow rate of the working fluid F running through the first loop L1. Certainly, the present invention is not limited thereto. For example, a plurality of tabs 114a may also stand at the first outlet E1 and the second outlet E2, so as to change the flow impedance to which the working fluid F is subject in the first loop L1 and the flow impedance to which the working fluid F is subject in the second loop L2. In the present invention, a shape, a size, a standing manner, or an arrangement manner of the tabs 114a can be designed according to a set location of the heat source 10. Therefore, the working fluid F is guided to a loop away from the heat source by using the tabs 114a, and takes most heat from a loop close to the heat source 10 to the loop away from the heat source 10 for dissipation. Therefore, the heat is dissipated, so that a temperature of the first loop L1 and a temperature of the second loop L2 can be balanced, achieving a heat dissipation effect.

A method for manufacturing the heat dissipation module 100b according to a second embodiment of the present invention further includes: enlarging a second outlet E2 and a pipe diameter of a second pipe 130, so that a flow rate of a working fluid F running through a second loop L2 is greater than a flow rate of the working fluid F running through the first loop L1. A method for manufacturing the heat dissipation module 100c according to a third embodiment of the present invention further includes: enabling at least one of the tabs 114a at the first outlet E1, so that the working fluid F is blocked by the tabs 114a when flowing from the first pipe 120 to the cavity 112a via the first outlet E1, and more working fluids F flow to the second loop L2. A method for manufacturing the heat dissipation module 100d according to a fourth embodiment of the present invention further includes: enabling some of the tabs 114a corresponding to the first loop L1 to obliquely stand in the cavity 112a, where some of the tabs 114a corresponding to the first loop L1 have a direction reverse to a flow direction of the working fluid F1, and some of the tabs 114a corresponding to the second loop L2 obliquely stand in the cavity 112a; some of the tabs 114a corresponding to the second loop L2 have a direction that is the same as a flow direction of the working fluid F1, so that the tabs 114a guide the working fluid F to flow from a first loop L1 having relatively high flow impedance to a second loop L2 having relatively low flow impedance. The method for manufacturing a heat dissipation module 100e according to a fifth embodiment of the present invention further includes: enabling some of the tabs 114a neighboring to a first outlet E1 and a second outlet E2 to stand and centralize towards the second outlet E2, so that flow impedance of the working fluid F in the first loop L1 is different from flow impedance of the working fluid F in the second loop L2.

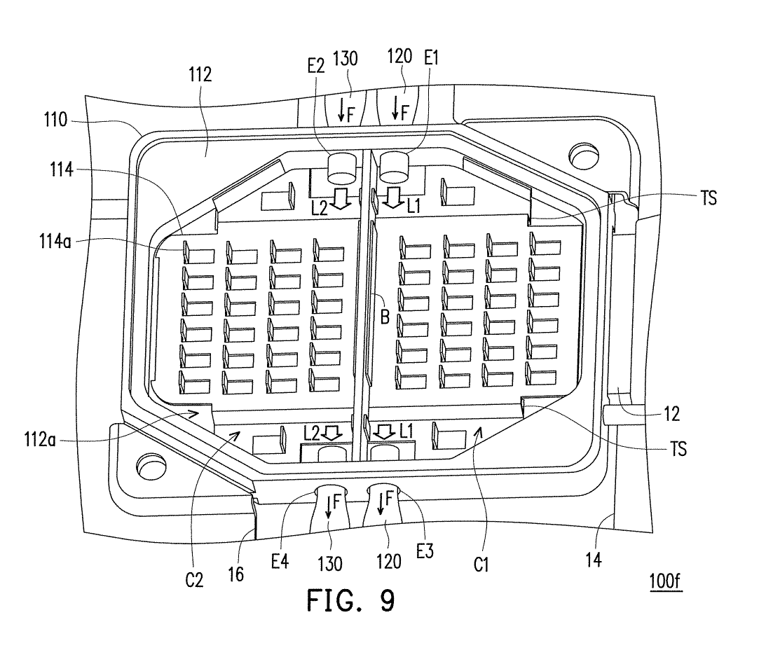

FIG. 9 is a locally enlarged diagram according to a sixth embodiment of the present invention. In the present embodiment, some of the tabs 114a of a heat dissipation module 100f form a division structure B, so as to divide the cavity 112a into two sub-cavities C1 and C2. A first loop L1 runs through one sub-cavity C1, and a second loop L2 runs through the other sub-cavity C2. For example, a height of the division structure B may be the same as a height of the cavity 112a, or less than a height of the cavity 112a, so that the working fluid F can still flow between the two sub-cavities C1 and C2. This is not limited in the present invention. In addition to forming the division structure B by some of the tabs 114a, some first sheet metals 114 may also function as the division structure B. Alternatively, the division structure B may also be integrated by a part of an evaporator 110 and the evaporator 110, as shown in FIG. 9. In this case, for example, two sheet metals may replace the first sheet metal 114, so that the sub-cavities C1 and C2 are separately provided with a sheet metal. However, this is not limited in the present invention.

Based on the above, in the heat dissipation module in the present invention, after a first pipe and a second pipe are connected to a cavity of an evaporator to respectively form a first loop and a second loop, a working fluid is filled in the cavity. Therefore, the working fluid can smoothly absorb heat when running through the evaporator, the working fluid is then converted into a vapor state, and the heat is taken away when the working fluid flows out of the cavity of the evaporator, so as to achieve a heat dissipation effect. The heat dissipation module in the present invention is provided with a first loop and a second loop in a single cavity. By controlling flows of the working fluids in the first loop and the second loop, the working fluid may take most heat from a relatively hot loop to a relatively cold loop for dissipation. Therefore, the heat is dissipated, so that a temperature of the first loop and a temperature of the second loop can be balanced, achieving a heat dissipation effect. In addition, the evaporator in the present invention includes a tank and a sheet metal installed in the tank. The sheet metal is provided with a plurality of tabs that are arranged and stand in the cavity, which not only can improve an area of contact between the working fluid and the evaporator and bring desirable heat exchanging efficiency, but also can guide the working fluid, so that the working fluid has relatively many flows in a loop away from the heat source, thereby achieving desirable heat dissipation effectiveness. In addition, a first sheet metal can assist, on an inclined plane corresponding to two side surfaces of a step structure, in guiding the working fluid to flow in and out of the cavity, so that the working fluid does not block a first outlet and a second outlet. In the method for manufacturing the heat dissipation module in the present invention, the first sheet metal is easy to machine and manufacture, multiple designs and arrangements of the tabs can be obtained by only stamping and then folding one sheet metal, and the first sheet metal can be reliably assembled with the tank by being pressed into the tank and through welding.

Even though the present invention is disclosed in the foregoing by using embodiments, the present invention is not limited thereto. Persons of ordinary skill in the art can make some modifications and polishing without departing from the spirit and scope of the present invention. Therefore, the protection scope of the present invention shall be subject to the claims that are appended subsequently.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A heat dissipation module, applicable to an electronic apparatus, the electronic apparatus having a heat source, and the heat dissipation module comprising:
an evaporator, comprising a tank and a first sheet metal installed in the tank, wherein the tank comprises a cavity, the first sheet metal comprises a plurality of tabs being arranged and standing in the cavity, and the evaporator is in thermal contact with the heat source to absorb heat generated by the heat source;
a first pipe, connected to the cavity to form a first loop; and
a working fluid, filled in the cavity and the first loop.

2. The heat dissipation module according to claim 1, wherein the tabs are formed by folding parts of the first sheet metal.

3. The heat dissipation module according to claim 1, wherein the tabs are arranged in an array.

4. The heat dissipation module according to claim 1, wherein the heat dissipation module further comprises a second pipe, the second pipe is connected to the cavity to form a second loop, the working fluid is guided in the cavity by the tabs to separately flow to the first loop and the second loop, and a flow rate of the working fluid running through the first loop is not equal to a flow rate of the working fluid running through the second loop.

5. The heat dissipation module according to claim 4, wherein the cavity comprises a first outlet to connect to the first pipe, and the cavity further comprises a second outlet to connect to the second pipe, the second outlet is larger than the first outlet, and a pipe diameter of the second pipe is greater than another pipe diameter of the first pipe.

6. The heat dissipation module according to claim 4, wherein at least one of the tabs stands at the first outlet to block portion of the working fluid flowing to the first outlet.

7. The heat dissipation module according to claim 4, wherein some of the tabs corresponding to the first loop obliquely stand in the cavity in a direction reverse to a flow direction of the working fluid, and some of the tabs corresponding to the second loop obliquely stand in the cavity in a direction forward to the flow direction of the working fluid.

8. The heat dissipation module according to claim 4, wherein the cavity comprises a first outlet to connect to the first pipe, and the cavity further comprises a second outlet to connect to the second pipe, and some of the tabs neighboring to the first outlet and the second outlet are centralized towards the second outlet.

9. The heat dissipation module according to claim 1, further comprising a heat pipe, wherein the heat pipe is in thermal contact between the heat source and the evaporator to transfer the heat generated by the heat source to the evaporator, wherein the heat pipe comprises a contact section abutting on the evaporator, an extending direction of the contact section is not parallel to a flow direction of the working fluid in the cavity, a portion of an external of the tank comprises a recess being formed a step structure at an internal of the tank, wherein the contact section is structurally contacted in the recess, and the tabs are located at a higher step portion of the step structure.

10. The heat dissipation module according to claim 4, wherein the cavity comprises a step structure having a higher step portion and two lower step portions, the two lower step portions are separately located at a joint between the cavity and the first pipe and at another joint between the cavity and the second pipe, the higher step portion is located between the two lower step portions, the step structure further comprises two side surfaces facing towards each other, the two side surfaces respectively face towards at least one inlet and at least one outlet of the cavity, the first sheet metal covers the higher step portion of the step structure, and an inclined plane is formed on a portion corresponding to the two side surfaces of the first sheet metal.

11. The heat dissipation module according to claim 4, further comprising a second sheet metal and a third sheet metal, wherein the first pipe is carried on the second sheet metal, the second pipe is carried on the third sheet metal, the second sheet metal covers the heat source, and a flow rate of the working fluid in the second loop is greater than a flow rate of the working fluid in the first loop.

12. The heat dissipation module according to claim 4, wherein some of the tabs form a division structure to divide the cavity into two sub-cavities, the first loop runs through one sub-cavity, and the second loop runs through the other sub-cavity.

13. The heat dissipation module according to claim 4, wherein flow impedance of the working fluid flowing in the first pipe is not equal to flow impedance of the working fluid flowing in the second pipe.

14. A method for manufacturing a heat dissipation module as claim 1, comprising:
stamping the first sheet metal to form a bottom portion and the plurality of tabs, wherein the tabs are formed by folding from the bottom portion;
pressing the first sheet metal into the tank to force the bottom portion being contacted with an inner bottom of the tank, wherein the tabs stand in the cavity; and
welding the first sheet metal to the tank.

15. The method for manufacturing a heat dissipation module according to claim 14, further comprising:
connecting the first pipe to the cavity to form the first loop; and
connecting a second pipe to the cavity to form a second loop.

16. The method for manufacturing a heat dissipation module according to claim 15, further comprising:
loading a second sheet metal to the first pipe to cover the heat source; and
loading a third sheet metal to the second pipe.

17. The method for manufacturing a heat dissipation module according to claim 14, further comprising:
covering a cover body to the tank to form a contained space.

18. The method for manufacturing a heat dissipation module according to claim 15, further comprising:
enlarging a diameter of the second pipe, wherein the second pipe and the cavity are connected at a second outlet; and
enlarging the second outlet.

19. The method for manufacturing a heat dissipation module according to claim 15, further comprising:
arranging at least one of the tabs to stand at a first outlet, wherein the first pipe and the cavity are connected at the first outlet.

20. The method for manufacturing a heat dissipation module according to claim 15, further comprising:
arranging some of the tabs to being obliquely standing in the cavity and corresponding to the first loop, wherein the tabs corresponding to the first loop stand in a manner of leaning against a flow direction of the working fluid; and
arranging some of the tabs to being obliquely standing in the cavity and corresponding to the second loop, wherein the tabs corresponding to the second loop stand in a manner of leaning forward to the flow direction of the working fluid.

21. The method for manufacturing a heat dissipation module according to claim 15, further comprising:
centralizing some of the tabs neighboring to a first outlet and a second outlet of the cavity towards the second outlet, wherein the first pipe is connected to the first outlet of the cavity, and the second pipe is connected to the second outlet of the cavity.
